(19) United States
(12) Patent Application Publication
(10) Pub. No.: US 2010/0243608 A1
(43) Pub. Date: Sep. 30, 2010

(54) PLASMA PROCESSING APPARATUS AND PLASMA PROCESSING METHOD

(75) Inventor: Chishio Koshimizu, Nirasaki (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/750,734

(22) Filed: Mar. 31, 2010

Related U.S. Application Data
(60) Provisional application No. 61/186,919, filed on Jun. 15, 2009.

(30) Foreign Application Priority Data
Mar. 31, 2009 (JP) 2009-086450

(51) Int. Cl. B44C 1/22; C23C 16/513

(52) U.S. Cl. 216/67; 156/345.1; 118/723 R; 427/569; 134/1.1

(57) ABSTRACT

There is provided a plasma processing apparatus capable of varying an AC ratio without installing a largely scaled-up movable unit. An etching apparatus 10, which performs a plasma process on a wafer W within a processing chamber, includes a control member which is installed such that at least a part of the control member is in contact with a plasma region within the processing chamber, and an impedance control circuit 210 which is connected with the control member and adjusts a ground capacitance of the plasma region by controlling an electrical connection state between the control member and a ground plane.

### CROSS-REFERENCE TO RELATED APPLICATION

This application claims the benefit of Japanese Patent Application No. 2009-086450 filed on Mar. 31, 2009 and U.S. Provisional Application Ser. No. 61/186,919 filed on Jun. 15, 2009, the entire disclosures of which are incorporated herein by reference.

### FIELD OF THE INVENTION

The present disclosure relates to a plasma processing apparatus and a plasma processing method for performing a plasma process on a target object to be processed. In particular, the present disclosure relates to a device for controlling an AC (Anode/Cathode) ratio.

### BACKGROUND OF THE INVENTION

A plasma potential is higher than its surrounding potential. For example, in a plasma processing space surrounded by a wall area Ca and a mounting table (wafer) area Cc inside a processing chamber illustrated in FIG. 1, when a bias potential is negative (a wafer potential is negative), i.e., if the wafer potential is lower than a wall potential (a ground), the plasma potential becomes higher than the wall potential by about 10 V to about 50 V. Meanwhile, when the bias potential is positive (the wafer potential is positive), i.e., if the wafer potential is higher than the wall potential (the ground), the plasma potential becomes higher than the wafer potential by about 10 V to about 50 V.

In order to meet a demand of a user who attempts to improve throughput by increasing an etching rate or the like to reduce a processing time, it is required to supply a high frequency power of a higher power level into the processing chamber. When a high frequency power of a higher power level is outputted from a high frequency power source, a sheath voltage on a wall surface becomes up to maximum 300 V. In this state, a sputtering force of ions in plasma exerted on the wall surface increases, and, thus, radicals in the plasma may not be deposited easily on the wall surface. Therefore, erosion of the wall surface may be increased.

The erosion of the wall surface can be prevented by increasing an AC ratio. The AC ratio indicates asymmetry between an anode electrode and a cathode electrode. For example, the AC ratio can be represented by a ratio between a wafer area and a wall area. As described below, a ratio of sheath voltages (sheath voltage on the wall/sheath voltage on the wafer) is proportional to the fourth power of a ratio of areas (wafer area/wall area). Therefore, if the AC ratio is increased by making the wall area larger than the wafer area, the sheath voltage on the wall surface can be efficiently suppressed to be low.

The simple way to increase the AC ratio is to make the processing chamber large. However, this way requires high manufacturing cost, and a plasma region becomes larger than necessary for the wafer size. Therefore, a ratio of the high frequency power acting on the wafer to the high frequency power supplied into the processing chamber is decreased, and, thus, there are concerns that energy efficiency would be decreased.

Accordingly, there has been proposed a device which can increase the AC ratio without making the processing chamber larger (see, for example, Patent Document 1). In Patent Document 1, a baffle plate moves down during process and moves up during cleaning. Therefore, during process, the ratio of the wall area to the wafer area is controlled to increase so as to increase the AC ratio, whereas during cleaning, the ratio of the wall area to the wafer area is controlled to decrease so as to decrease the AC ratio.

Patent Document 1: Japanese Patent Laid-open Publication No. H10-321605

However, if a movable baffle plate or mounting table is moved up and down, dust may be generated from its movable unit or abnormal electric discharge may occur. As a result, contamination occurs or plasma becomes unstable, so that a favorable plasma process cannot be performed on a target object, resulting in a decrease in production yield and productivity.

Further, in case of simply increasing the AC ratio, an ion attack force on a wall is too small in some processes, and, thus, an unnecessary deposit is deposited on the wall. Recently, various kinds of processes are performed in a single chamber. For example, after a process using a CF-based gas, if the next process is performed in a state that the CF-based gas is deposited on the wall, reliability of the next process may be deteriorated. Meanwhile, an optimum value of the AC ratio varies depending on the processes. Therefore, in order to prevent the wall from being eroded too much or to prevent deposits from being deposited too much on the wall, it is necessary to appropriately adjust the AC ratio for each process.

### BRIEF SUMMARY OF THE INVENTION

In view of the foregoing, the present disclosure provides a plasma processing apparatus and a plasma processing method capable of varying an AC ratio without installing a scaled-up movable unit.

In accordance with an aspect of the present disclosure, there is provided a plasma processing apparatus which performs a plasma process on a target object in a plasma processing space within a processing chamber. The plasma processing apparatus includes a control member which is installed such that at least a part of the control member is in contact with a plasma region within the processing chamber; and an impedance control circuit which is connected with the control member and adjusts a ground capacitance of the plasma processing space by controlling an electrical connection state between the control member and a ground plane.

In the plasma processing apparatus, the control member is installed such that at least a part of the control member is in contact with the plasma region within the processing chamber. The impedance control circuit connected with the control member varies an electrical connection state between the control member and a ground plane. Accordingly, the control member can be in a ground state or in a floating state.

If the control member is set to be in the ground state, a ground area of a wall becomes relatively larger than a wafer area, and, thus, an AC ratio increases. Therefore, a sheath voltage on a wall surface decreases. Accordingly, by reducing an acceleration of ions in a sheath region on the wall surface, an ion attack force on the wall can be decreased, so that erosion of the wall surface can be suppressed.

Meanwhile, if the control member is set to be in the floating state, the ground area of the wall becomes relatively smaller than the wafer area, and, thus, the AC ratio decreases. Therefore, the sheath voltage on the wall surface increases. Accordingly, the ion attack force on the wall can be increased, so that it is possible to prevent deposits such as radicals from being deposited on the wall.

In this way, by varying the AC ratio, an attack force of the ions exerted on the wall surface can be adjusted for each process without installing a scaled-up movable unit. Accordingly, it is possible to prevent the wall from being eroded too much or prevent deposits from being deposited too much on the wall.

The impedance control circuit may include a switch one end of which is grounded, and adjust a ground area of the control member by using the switch, thereby adjusting the ground capacitance of the plasma processing space.

The impedance control circuit may include a variable capacitor, and adjust an electrical connection state of the control member by using the variable capacitor, thereby adjusting the ground capacitance of the plasma processing space.

The control member may be parallel to an exhaust direction.

The control member may be provided in an inner space of a baffle plate positioned at an outer periphery of a mounting table.

The control member may include plural sheets of adjustment members radially arranged around a center of the baffle plate.

The control member may include one or more sheets of adjustment members arranged around a center of the baffle plate in a circumferential direction.

Plural sheets of the adjustment members may be equi-spaced, or plural sheets of the adjustment members may be symmetrically arranged.

At least one of a plurality of switches and a plurality of variable capacitors included in the impedance control circuit may have a one-to-one connection with each of the plural sheets of the adjustment members.

The impedance control circuit may adjust the ground capacitance of the plasma processing space by controlling each of the switches or each of the variable capacitors.

The plasma processing apparatus may further include a controller which includes a memory and controls the impedance control circuit based on a recipe previously stored in the memory.

In accordance with another aspect of the present disclosure, there is provided a plasma processing method using a plasma processing apparatus which performs a plasma process on a target object in a plasma processing space within a processing chamber. The plasma processing method includes installing a control member in the plasma processing apparatus such that at least a part of the control member is in contact with a plasma region within the processing chamber; and adjusting a ground capacitance of the plasma processing space by way of controlling an electrical connection state between the control member and a ground plane by an impedance control circuit connected with the control member.

As described above, in accordance with the present disclosure, it is possible to provide a plasma processing apparatus and a plasma processing method capable of varying an AC ratio without installing a scaled-up movable unit.

### BRIEF DESCRIPTION OF THE DRAWINGS

The disclosure may best be understood by reference to the following description taken in conjunction with the following figures:

FIG. 1 is a longitudinal cross-sectional view of an overall configuration of a plasma processing apparatus in accordance with a first embodiment of the present disclosure;

FIG. 2 is a view for explaining a configuration of a baffle plate and fins serving as control members in accordance with the first embodiment;

FIG. 3 is a view showing a part of the fins and an impedance control circuit in accordance with the first embodiment;

FIG. 4 is a view of a modified example of the control member in accordance with the first embodiment;

FIG. 5 is a view of a modified example of the impedance control circuit in accordance with the first embodiment;

FIG. 6 is a longitudinal cross-sectional view of an overall configuration of a plasma processing apparatus in accordance with a second embodiment of the present disclosure;

FIGS. 7A and 7B provide modified examples of a control member in accordance with the second embodiment;

FIG. 8 is a view for explaining a relationship between an AC ratio and a voltage ratio; and

FIG. 9 is a graph for showing a relationship between an AC ratio and a wall potential.

### DETAILED DESCRIPTION OF THE INVENTION

Hereinafter, embodiments of the present invention will be described in detail with reference to the accompanying drawings. In addition, same parts having the substantially same function and configuration will be assigned same reference numerals through the whole document, and redundant description thereof will be omitted.

### First Embodiment

### Overall Configuration of Plasma Processing Apparatus

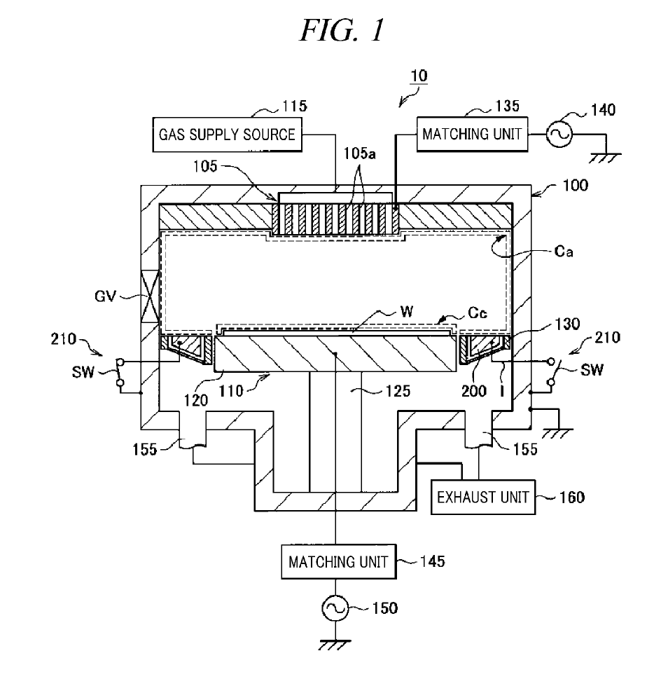

Referring to FIG. 1, there will be explained an overall configuration of a plasma processing apparatus in accordance with a first embodiment. FIG. 1 is a longitudinal cross-sectional view schematically showing a capacitively coupled type (parallel-plate type) etching apparatus. An etching apparatus 10 is an example of a plasma processing apparatus for performing a plasma process on a target object within a processing chamber.

The etching apparatus 10 includes a processing chamber 100 in which a wafer W loaded through a gate valve GV is plasma-processed. The processing chamber 100 has a cylindrical shape, and is made of metal such as aluminum, and is grounded.

Inside the processing chamber, there are installed an upper electrode 105 and a lower electrode 110 facing each other, which serve as a pair of parallel plate electrodes. A surface of the upper electrode 105 is thermally sprayed with alumina or yttria. The upper electrode 105 is penetrated by a plurality of gas holes 105a through which a gas supplied from a gas supply source 115 is introduced into the processing chamber.

In the lower electrode 110, a mounting table 120 which mounts thereon the wafer W is provided. The mounting table 120 is made of metal such as aluminum and supported by a support member 125 via a non-illustrated insulator. Therefore, the lower electrode 110 is in an electrically floating state. Installed around an outer periphery of the mounting table 120 is a baffle plate 130 which controls a gas flow. The baffle plate 130 is grounded. A configuration of the baffle plate 130 will be explained in detail later.

The upper electrode 105 is connected with a high frequency power supply 140 via a matching unit 135. A gas supplied from the gas supply source 115 is excited into plasma by an electric field energy of a high frequency of, e.g., about 60 MHz outputted from the high frequency power supply 140. An etching process is performed on the wafer by using the electric discharge plasma generated in this way.

The lower electrode 110 is connected with a high frequency power supply 150 for outputting a high frequency power of, e.g., about 2 MHz via a matching unit 145. By applying a bias voltage onto the mounting table 120 through the high frequency power supply 150, the amount of ions attracted to the mounting table 120 is increased.

Installed at a bottom surface of the processing chamber 100 is an exhaust port 155, and an exhaust unit 160 connected with the exhaust port 155 evacuates the inside of the processing chamber 100 so as to maintain the inside of the processing chamber at a desired vacuum level.

A plasma processing space in the present embodiment is positioned above the mounting table 120 and the baffle plate 130 and surrounded by a wall area Ca and a wafer area Cc within the processing chamber.

A plasma region in the present embodiment is a region where plasma exists in the plasma processing space and is positioned above the baffle plate.

A plasma potential of the plasma region near an electrode to which a high frequency power (RF) is applied is higher than its surrounding potential. For example, in the plasma processing space surrounded by the wafer area Cc, if a bias potential is negative (a wafer potential is negative), i.e., if the wafer potential is lower than a wall potential (a ground), the plasma potential becomes higher than the wall potential by about 10 V to about 50 V. Meanwhile, if the bias potential is positive (the wafer potential is positive), i.e., if the wafer potential is higher than the wall potential (the ground), the plasma potential becomes higher than the wafer potential by about 10 V to about 50 V

### (Principle of Ac Ratio)

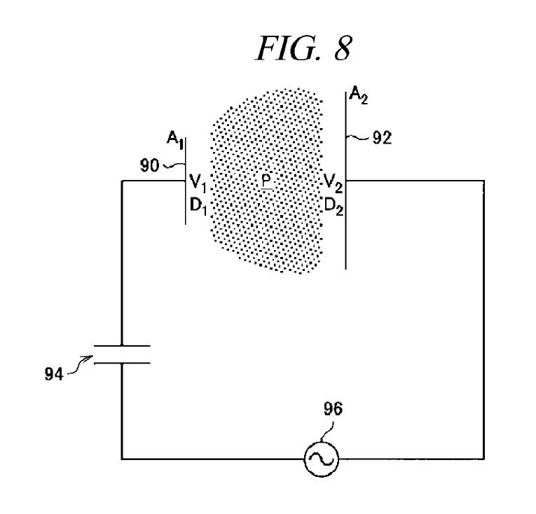

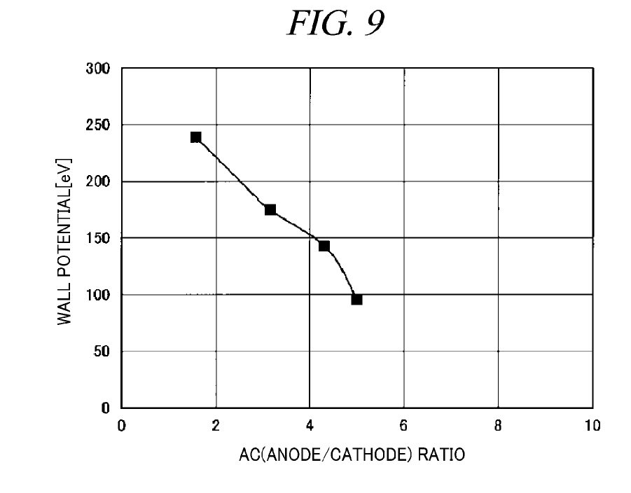

Hereinafter, there will be explained a principle of an AC ratio with reference to FIGS. 8 and 9. In a book entitled “Basic Plasma Processing” (written by Brian N. Chapman, and published by Denkishoin in Japan), there is a description about “a voltage distribution near an electrode when using a blocking capacitor” as below.

As depicted in FIG. 8, in consideration of a relationship between areas A₁ and A₂ (A₁≠A₂) of two electrodes 90 and 92, each of sheath voltages V₁ and V₂ and sheath thicknesses D₁ and D₂ can be expressed by using the areas of the electrodes for a high frequency discharge. FIG. 8 shows a voltage distribution near electrodes when a high frequency power is supplied from a high frequency power supply 96 via a blocking capacitor 94.

At this time, positive ions of a mass mᵢ are generated in a glow space; fly through a dark space without any collision with each other; and flow with a space charge limited current jᵢ.

jᵢ=KV^{3/2}/mᵢ^{1/2}D² (K: constant)

Further, since a current density of the positive ions is uniform, the current density is the same at both electrodes. With these two assumptions, the following equation is obtained.

V₁^{3/2}/D₁²=V₂^{3/2}/D₂² (1)

A capacitance of the dark space is proportional to the area of the electrode and inversely proportional to a sheath thickness.

C∝A/D (2)

A high frequency voltage is capacitively divided into two capacities.

V₁/V₂=C₂/C₁ (3)

By a combination of the equations (2) and (3), the following equation can be obtained.

V₁/V₂=A₂/D₂×D₁/A₁

When the above equation is substituted for the equation (1), the following equation can be obtained.

V₁/V₂=(A₂/A₁)⁴ (4)

The equation (4) implies the following two facts:

(a) A larger sheath voltage is applied to a smaller electrode.

(b) The fourth power of asymmetry (A₂/A₁) between the electrodes is proportional to a ratio of voltages (V₁/V₂).

In FIG. 9, the horizontal axis represents an AC ratio and the vertical axis represents a wall potential. In this case, the wafer serves as an anode electrode and the wall serves as a cathode electrode. At this time, a high frequency voltage of a high power was applied and an ion energy incident to the wall was measured by a QSM installed at the wall. It can be seen from a result of the measurement that as the AC ratio increases, the ion energy incident to the wall decreases.

(AC Ratio Varying Mechanism)

Therefore, if the AC ratio increases, energy incident to the wall decreases, and thus it is possible to prevent the wall from being eroded. There are two ways to increase the AC ratio. One way is to make a processing chamber larger, and the other way is to move a movable baffle plate or mounting table up and down. However, in case of making the processing chamber large, a plasma region becomes larger than necessary and a ratio of power applied to a wafer is decreased. In case of moving the baffle plate or the like up and down, dust may be generated from its movable unit or abnormal electric discharge may occur. An optimum value of the AC ratio varies depending on the processes. Therefore, in case of simply increasing the AC ratio, an ion attack force on the wall may be too small in some processes.

(AC Ratio Control Members/Fins)

In the present embodiment, a plurality of fins for controlling the AC ratio are installed in an inner space of the baffle plate 130 so as to variably control the AC ratio without installing a scaled-up movable unit. There will be explained a mechanism inside the baffle plate 130 with reference to FIGS. 1 to 3.

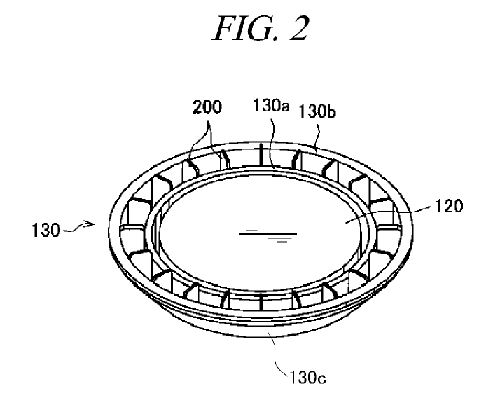

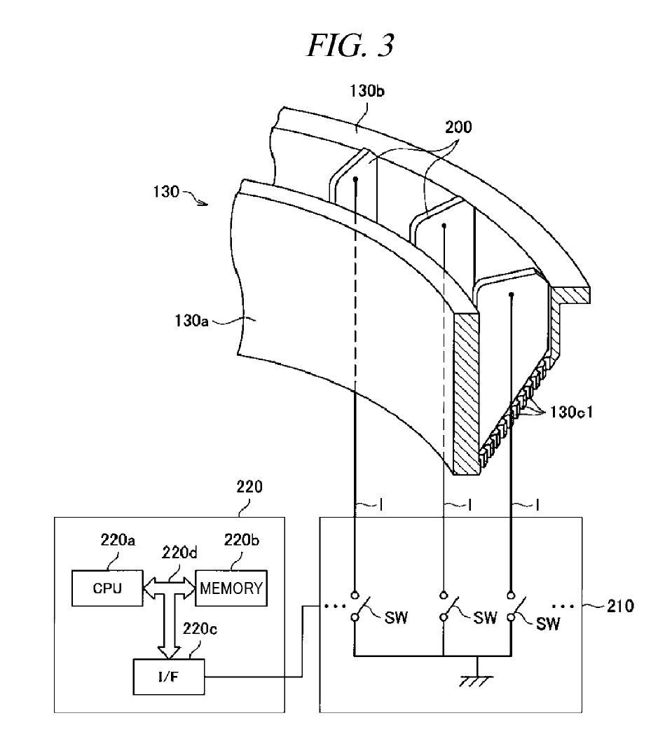

As depicted in FIGS. 1 and 2, the baffle plate 130 is formed in a ring shape and arranged at an outer periphery of the mounting table 120. As can be seen from FIG. 3 showing an expanded view of a part of the baffle plate 130, there is formed a hollow region between an inner circumference wall 130a and an outer circumference wall 130b of the baffle plate 130. A bottom surface 130c of the baffle plate 130 is inclined and provided with a plurality of holes 130c1 for evacuating a gas. The baffle plate 130 is grounded.

Plate-shaped fins 200 are installed in the inner space of the baffle plate 130 not to be in contact with the baffle plate 130. A lower portion of the plate-shaped fin 200 is inclined in the same direction as the inclined bottom surface of the baffle plate 130. The fin 200 is an example of a control member which is configured to bring at least a part of the control member into contact with the plasma region inside the processing chamber 100.

As depicted in FIG. 2, 24 sheets of the fins 200 are radially arranged around the center of the baffle plate 130. The fins 200 are parallel to an exhaust direction and symmetrically equi-spaced. This configuration does not interfere with a flow of the processing gas and allows conductance to be kept in a favorable condition. In order to increase the AC ratio, the number of the fins 200 may be increased without adversely affecting the conductance. Alternatively, only one fin 200 can be provided. If plural fins 200 are provided, electric current paths from the respective fins 200 to the ground may be symmetrical to one another, desirably.

The fins 200 may be made of aluminum Al coated with an insulating film made of yttria (Y₂O₃), or the fins 200 may be alumite-treated. Further, the fins 200 may have a structure in which metal and an insulating film are coated on a surface of a dielectric member.

As depicted in FIGS. 1 and 3, the fins 200 are connected with an impedance control circuit 210 which controls an electrical connection state of the fins 200. The impedance control circuit 210 includes switches SW each connected with each one of 24 sheets of the fins 200. The fins 200 are connected with the switches SW through power feed rods (lines) 1, respectively. Each of the fins 200 is connected with the switch SW outside the processing chamber 100 as depicted in FIG. 1. The other end of the switch SW is connected with the processing chamber 100 and grounded.

Although not illustrated, the power feed rods 1 are covered with a protection member such as quartz and connected with the switches SW by penetrating a sidewall of the processing chamber 100. Since the power feed rods 1 are covered with the protection member made of an insulating material, the fins 200 are not in a short circuit.

Referring to FIG. 3 again, the impedance control circuit 210 is connected with a controller 220. The controller 220 includes a CPU 220a, a memory 220b, and an interface (I/F) 220c each of which is configured to exchange signals through an internal bus 220d.

The memory 220b stores in advance recipes for controlling on/off of each switch SW of the impedance control circuit 210. The recipes specify the number and a position of the fin 200 to be grounded by changing a switch to be on in each process. The CPU 220a selects a recipe corresponding to a process to be performed and controls on/off of each switch SW based on the selected recipe.

Accordingly, a ground area of the fins 200 varies depending on the number of the grounded fins 200, and, thus, the AC ratio can be adjusted based on the equation (4). For example, when the controller 220 controls the switch SW to be turned off, each fin 200 is in a floating state. On the contrary, when the switch SW is turned on, the fin 200 is in a ground state.

By increasing the number of the switches SW to be on, the number of the fins 200 to be grounded can be increased. Therefore, a ground area ratio of the wall area Ca to the wafer area Cc in FIG. 1 becomes relatively large. Accordingly, the AC ratio is increased and, thus, the sheath voltage on the wall area Ca can be decreased. As a result, an ion sputtering force exerted on the wall can be decreased, whereby it is possible to prevent the wall from being eroded.

For example, the wall is severely eroded during a process requiring a high power. In order to avoid such erosion, the number of the fins 200 to be grounded increases by increasing the number of the switches SW to be on. Therefore, by increasing the AC ratio, the sheath voltage on the wall area Ca decreases. In this way, an attack force of the ions exerted on the wall surface can be reduced, and, thus, it is possible to prevent the wall from being eroded.

By increasing the number of the switches SW to be off, the number of the grounded fins 200 can be reduced. Therefore, a ground area ratio of the wall area Ca to the wafer area Cc in FIG. 1 becomes relatively small. Accordingly, the AC ratio is decreased and, thus, the sheath voltage on the wall area Ca can be increased. As a result, the ion sputtering force exerted on the wall can be increased, whereby it is possible to prevent deposits from being deposited on the wall.

For example, radicals or the like may be readily deposited on the wall during a process requiring a low power. In order to avoid such a deposition, by controlling the switches SW to be off, the fins 200 are in the floating state, so that the AC ratio decreases. Accordingly, the sheath voltage on the wall area Ca increases so that the attack force on the wall can be increased. As a result, deposition of the deposits can be suppressed.

In a plasma cleaning process requiring a relatively low power, a cleaning time is increased due to a decrease in the number of the ions attacking the wall. To avoid such an increase of a cleaning time, by controlling the switches SW to be off, the fins 200 are in a floating state, so that the AC ratio decreases. Accordingly, the sheath voltage on the wall area Ca increases so that the attack force on the wall can be increased.

As described above, in accordance with the present embodiment, the sheath voltage on the wall area can be appropriately adjusted for each process by controlling the switches SW, and, thus, it is possible to prevent the wall from being eroded too much or prevent deposits from being deposited too much on the wall. Accordingly, a high-speed etching can be performed without increasing a chamber size or a power of a high frequency power supply, whereby it is possible to reduce manufacturing cost, improve footprint, and save energy. Further, even in case of a cleaning process or a mask process requiring a low high-frequency power, the process can be performed at a high speed and a deposition state of deposits on the wall becomes stable, whereby controllability of the process can be improved.

Further, in the present embodiment, 24 sheets of the fins 200 are arranged and each of them is connected with each switch SW, and, thus, it is possible to accurately control a ground state of the fin 200 by controlling each switch SW.

For example, if a voltage ranging from about 1000 V to about 2000 V needs to be applied to the lower electrode 110 to etch an oxide film on the wafer, it is desirable to increase the AC ratio so as to provide high ion energy to the wafer. To increase the AC ratio, a lot of fins 200 are turned into the ground state. Meanwhile, if energy on the wafer needs to be decreased and energy for attacking the wall needs to be increased, it is desirable to decrease the AC ratio. To decrease to AC ratio, a lot of fins 200 are turned into the floating state. In this way, by varying the number of the fins 200 to be grounded, it is possible to accurately adjust a deposition state of deposits on the wall and a sputtering state on the wall without requiring a unit for moving the mounting table or the like.

When the respective fins 200 are turned into a ground state or a non-ground state, it is desirable that the grounded fins 200 may be equi-spaced as symmetrically as possible. With this configuration, the deposits may be uniformly deposited on the wall and the wall may be uniformly eroded.

Further, as for a switching unit, a mechanical switch, a relay switch, and a semiconductor switch can be used. Furthermore, during the process, it is possible to variably make an on/off operation of the switch and adjust a time for making the on/off operation according to the description in the recipe.

### Modified Example 1 of First Embodiment

### AC Ratio Control Member/Ring-Shaped Member

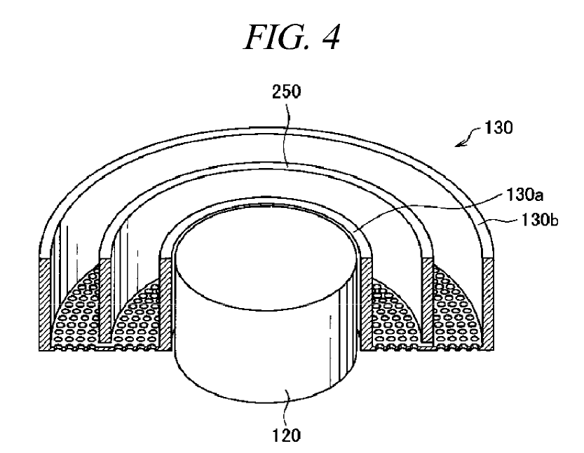

As for the control member, a ring-shaped member 250 as depicted in FIG. 4 may be used instead of the fins 200. The ring-shaped member 250 is installed in an inner space of the baffle plate 130 and is not in contact with the baffle plate 130 in the same manner as the fins 200. Although one sheet of the ring-shaped member 250 is installed in a circumferential direction of the baffle plate 130, two or more sheets may be installed. The ring-shaped member 250 is parallel to an exhaust direction so as not to interfere with a flow of the processing gas, whereby conductance can be kept in a favorable condition. The ring-shaped member 250 is equi-spaced between the inner circumference wall 130a and the outer circumference wall 130b of the baffle plate 130.

In the present modified example, the ring-shaped member 250 can also be controlled to be in a ground or non-ground state by an on/off operation of a switch SW of the impedance control circuit 210 not illustrated in FIG. 4, whereby the AC ratio can be adjusted based on the equation (4). Accordingly, it is possible to prevent the wall from being eroded too much or prevent deposits from being deposited too much on the wall.

### Modified Example 2 of First Embodiment

### Impedance Control Circuit

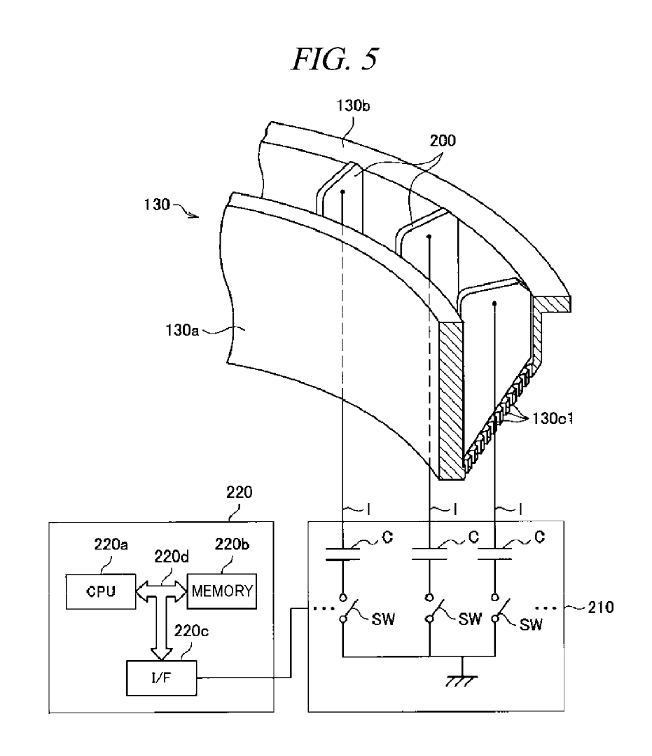

As another example, the impedance control circuit 210 may be configured to add constant capacitors C illustrated in FIG. 5 between the fins 200 and the switches SW to the configuration of the switch as explained in the first embodiment. Accordingly, a combination of a plurality of the constant capacitors C and a plurality of switches SW serves as a variable capacitor. Other types of Variable capacitors may be used in the impedance control circuit 210.

In the first embodiment, the ground area of the fins 200 is adjusted by using the switches SW one ends of which are grounded, thereby adjusting its ground capacitance. However, in the modified example 2, the electrical connection state of the fins 200 is adjusted by using the variable capacitor, thereby adjusting its ground capacitance.

According to the equations (3) and (4), equation (5) can be derived.

V₁/V₂=(A₂/A₁)⁴=C₂/C₁ (5)

According to this equation, the AC ratio can be determined by using a capacitance ratio between the wall area Ca and the wafer area Cc instead of the area ratio between the wall area Ca and the wafer area Cc. Although the switch SW can make only two values, i.e., a ground value and a non-ground value by on on/off operation of the switch SW, the impedance control circuit 210 including the variable capacitor can vary the ground capacitance continuously.

To be specific, as a capacitance of the variable capacitor increases, the ground capacitance increases, whereas as the capacitance of the variable capacitor decreases, the ground capacitance decreases. Therefore, as the number of the switches SW to be on increases, the fins 200 are getting closer to the ground state, and a ratio of a wall area Ca's sheath capacitance to a wafer area Cc's sheath capacitance can be increased, thereby increasing the AC ratio. Accordingly, it is possible to prevent the wall from being eroded.

On the contrary, as the number of the switches SW to be off increases, the fins 200 are getting closer to the floating state, and the ratio of the wall area Ca's sheath capacitance to the wafer area Cc's sheath capacitance can be decreased, thereby decreasing the AC ratio. Accordingly, it is possible to prevent radicals from being deposited on the wall.

As described above, in accordance with the present embodiment and its modified examples, the ground area and the ground capacitance of the wall can be varied using the control member, thereby controlling the AC ratio. Accordingly, it is possible to adjust an erosion state of the wall or a deposition state of deposits on the wall.

### Second Embodiment

### Overall Configuration of Plasma Processing Apparatus

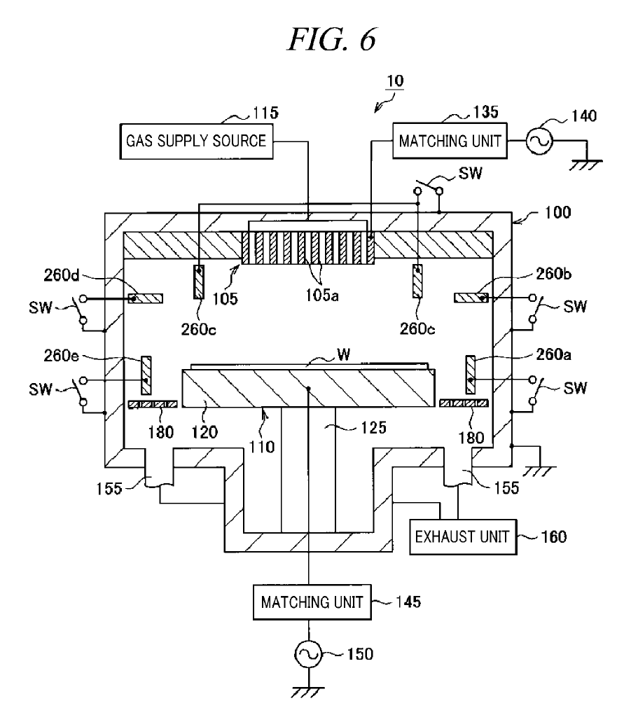

Hereinafter, there will be explained an overall configuration of a plasma processing apparatus in accordance with a second embodiment of the present disclosure with reference to FIG. 6. In the present embodiment, bar-shaped members 260a, 260b, 260d and 260e or a ring-shaped member 260c each serving as a control member are arranged such that at least a part of them is in contact with a plasma region.

In the present embodiment, the bar-shaped members 260a, 260b, 260d and 260e or the ring-shaped member 260c can also be controlled to be in a ground or non-ground state by making an on/off operation of switches SW, so that an AC ratio can be adjusted so as to vary a sheath voltage on a wall. Accordingly, an ion attack force on the wall can be adjusted, and, thus, it is possible to prevent the wall from being eroded too much or prevent deposits from being deposited too much on the wall.

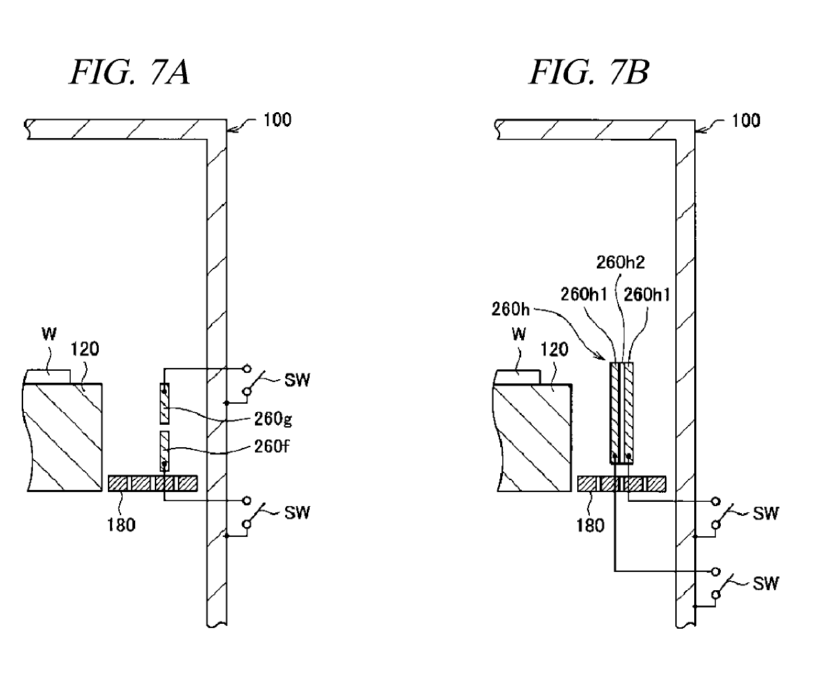

FIGS. 7A and 7B illustrate other configuration examples of the bar-shaped or ring-shaped control members. Each of bar-shaped or ring-shaped control members 260f and 260g is parallel to an exhaust direction so as not to interfere with a flow of a processing gas but so as to increase a surface area of the control members as large as possible. Desirably, each of the control members 260f and 260g may be arranged so as not to interfere with a wafer transfer and distanced away from a vicinity of the wafer or the upside of the wafer. For example, each of the control members 260f and 260g may be arranged at an outer periphery of a mounting table 120 or at an outer periphery of the upside of the wafer as illustrated in FIG. 7A. With such an arrangement, contamination may be avoided.

In FIG. 7B, a bar-shaped or ring-shaped control member 260h is configured to sandwich an insulating member 260h2 between two sheets of conductive members 260h1 whose surfaces are covered with an insulating material. Each conductive member 260h1 is connected with a switch SW, and, thus, each conductive member 260h1 can be independently controlled to be in a ground or non-ground state by making an on/off operation of each switch SW. Accordingly, it is possible to control a ground state of each surface of both sides of the control member 260h.

In the present embodiment, a sheath voltage on the wall area can also be appropriately adjusted for each process by controlling the switches SW, and, thus, it is possible to prevent the wall from being eroded too much or prevent deposits from being deposited too much on the wall.

As described above, at least a part of the control member is in contact with a plasma region, and the AC ratio is varied by using the control member. Accordingly, the ion energy colliding with the wall is increased or decreased by adjusting the ground capacitance of the wall area, so that it is possible to control erosion of the wall or deposition of deposits on the wall.

This configuration does not require a largely scaled-up structure such as a movable mounting table or baffle plate, and, thus, it has an advantage of cost or footprint. Further, the plasma processing space does not become larger than necessary, and, thus, there is no need to set a high frequency power to be higher than necessary. Therefore, unnecessary energy consumption can be suppressed.

In the above-described embodiments, the operations of the respective components of the plasma processing apparatus are interrelated and can be substituted with a series of operations in consideration of such interrelation. By the substitution, the embodiment of the plasma processing apparatus can be used as an embodiment of a plasma processing method of using the plasma processing apparatus.

There have been explained the embodiments of the present invention in detail with reference to the accompanying drawings, but it is clear that the above-described embodiments are illustrative in all aspects and do not limit the present invention. It would be understood by those skilled in the art that various changes and modifications may be made without changing technical conception and essential features described in the following claims and their equivalents are included in the scope of the present invention.

For example, the control member in accordance with the present disclosure may be formed in a plate shape or a bar shape. The control member in accordance with the present disclosure may be formed in a zigzag shape. If a plurality of control members each having a small surface area is provided, a ground area thereof can be accurately adjusted. On the contrary, if a control member having a large surface area is provided, an AC ratio can be greatly adjusted.

Further, the plasma processing apparatus in accordance with the present disclosure is not limited to the etching apparatus and can be any kind of apparatus capable of performing a plasma process such as asking, surface modification, or CVD (Chemical Vapor Deposition).

Furthermore, the target object which is plasma-processed by the plasma processing apparatus of the present disclosure is not limited to a silicon wafer and can be a substrate for FPD (Flat Panel Display) or a substrate for a solar cell.

What is claimed is:

1. A plasma processing apparatus which performs a plasma process on a target object in a plasma processing space within a processing chamber, the apparatus comprising:
a control member which is installed such that at least a part of the control member is in contact with a plasma region within the processing chamber; and
an impedance control circuit which is connected with the control member and adjusts a ground capacitance of the plasma processing space by controlling an electrical connection state between the control member and a ground plane.

2. The plasma processing apparatus of claim 1, wherein the impedance control circuit includes a switch one end of which is grounded, and adjusts a ground area of the control member by using the switch, thereby adjusting the ground capacitance of the plasma processing space.

3. The plasma processing apparatus of claim 1, wherein the impedance control circuit includes a variable capacitor, and adjusts an electrical connection state of the control member by using the variable capacitor, thereby adjusting the ground capacitance of the plasma processing space.

4. The plasma processing apparatus of claim 1, wherein the control member is parallel to an exhaust direction.

5. The plasma processing apparatus of claim 4, wherein the control member is provided in an inner space of a baffle plate positioned at an outer periphery of a mounting table.

6. The plasma processing apparatus of claim 5, wherein the control member includes plural sheets of adjustment members radially arranged around a center of the baffle plate.

7. The plasma processing apparatus of claim 5, wherein the control member includes one or more sheets of adjustment members arranged around a center of the baffle plate in a circumferential direction.

8. The plasma processing apparatus of claim 6, wherein plural sheets of the adjustment members are symmetrically arranged.

9. The plasma processing apparatus of claim 6, wherein plural sheets of the adjustment members are equi-spaced.

10. The plasma processing apparatus of claim 6, wherein at least one of a plurality of switches and a plurality of variable capacitors included in the impedance control circuit has a one-to-one connection with each of the plural sheets of the adjustment members.

11. The plasma processing apparatus of claim 10, wherein the impedance control circuit adjusts the ground capacitance of the plasma processing space by controlling each of the switches or each of the variable capacitors.

12. The plasma processing apparatus of claim 1, further comprising:
a controller which includes a memory and controls the impedance control circuit based on a recipe previously stored in the memory.

13. A plasma processing method using a plasma processing apparatus which performs a plasma process on a target object in a plasma processing space within a processing chamber, the method comprising:
installing a control member in the plasma processing apparatus such that at least a part of the control member is in contact with a plasma region within the processing chamber; and
adjusting a ground capacitance of the plasma processing space by way of controlling an electrical connection state between the control member and a ground plane by an impedance control circuit connected with the control member.
